(19) United States
(12) Patent Application Publication
(10) Pub. No.: US 2008/0253065 A1
(43) Pub. Date: Oct. 16, 2008

(54) FIXING MECHANISM

(75) Inventor: Kun-Hui Lai, Taipei City (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/765,825

(22) Filed: Jun. 20, 2007

(30) Foreign Application Priority Data
Apr. 13, 2007 (TW) 96112994

(51) Int. Cl. H05K 7/00

(52) U.S. Cl. 361/679

(57) ABSTRACT

A fixing mechanism for being assembled with an electronic device having a first limiting portion to fix a removable device in the electronic device and including a body, a positioning unit, and at least one elastic element is provided. The body is disposed in the electronic device and the positioning unit is located at one side of the body. The elastic element is connected to the body and includes two symmetric arms and a second limiting portion. The lengths of the arms are equal. One end of each arm is connected to the body respectively, and the second limiting portion is connected between the arms. The body is suitable to move relative to the electronic device along a first direction to make the first limiting portion move along the elastic element. The second limiting portion is suitable for limiting the first limiting portion moving along the elastic element.

### CROSS-REFERENCE TO RELATED APPLICATION

This application claims the priority benefit of Taiwan application serial no. 96112994, filed Apr. 13, 2007. All disclosure of the Taiwan application is incorporated herein by reference.

### BACKGROUND OF THE INVENTION

1. Field of the Invention

The present invention relates to a fixing mechanism. More particularly, the present invention relates to a fixing mechanism disposed on a housing of an electronic device.

2. Description of Related Art

With the development of science and technology, people increasingly rely much on electronic devices. Portable electronic device are gradually popularized by consumers due to the characteristics of being light, thin, short, and small. In order to further reduce the weight of portable electronic devices for the convenience of carrying or maintenance for users, portable devices usually have detachable units.

For example, disc drivers of some notebook PCs usually may be detached for the convenience of maintenance. In addition, the batteries of the notebook PCs are usually detachable, such that users can change the batteries, thereby elongating the service life of notebook PCs. In order to make users to detach or fix a removable device or a battery conveniently, a notebook PC often has a fixing mechanism. When a user pushes the fixing mechanism to a locking position, the removable device or the battery is fixed in a corresponding slot of the notebook PC. When the user pushes the fixing mechanism to a release position, the user detaches the removable device or the battery from the corresponding slot.

FIG. 1 is a schematic structural view of a conventional notebook PC, FIGS. 2A and 2C are schematic structural views of the release position and the locking position of the fixing mechanism in FIG. 1, FIG. 2B is a sectional view of FIG. 2A taken along a section line I-I′, and FIG. 2D is a sectional view of FIG. 2C taken along a section line II-II′. Referring to FIGS. 1-2D, the notebook PC 100 includes a mainframe body 110, a removable device 120, and a fixing mechanism 130. The mainframe body 110 has a slot 112 and the removable device 120 is suitable to be assembled in the slot 112. The fixing mechanism 130 is assembled in a housing 114 of the mainframe body 110 and disposed adjacent to the slot 112. The fixing mechanism 130 includes a push button 132 (in FIG. 1) and a body 134a. The push button 132 is disposed in a sliding slot 116 (in FIG. 1) in the outer surface of the housing 114, and two hooks 1322 pass through a hole 118 in the sliding slot 116 and a mounting hole 1342 of the body 134a in the inner surface of the housing 114. When the fixing mechanism 130 is removed from the release position (in FIGS. 2A and 2B) to the locking position (in FIGS. 2C and 2D), a positioning pin 1344 of the body 134a is inserted into a positioning hole 122 of the removable device 120, such that the removable device 120 is retained in the slot 112 of the body 110.

In the conventional art, the mainframe body 110 further has a bump 119 on the inner surface of the housing 114 and the fixing mechanism 130 further has an elastic element 136 and a stopper 138 connected to the elastic element 136 and corresponding to the bump 119. The fixing mechanism 130 is retained in the release position or the locking position by using the bump 119 to block the stopper 138.

When pushing the push button 132 to move the fixing mechanism 130 from the release position to the locking position, the user must provide a first external force F1 to make the elastic element 136 generate elastic deformation in the direction indicated by an arrow 140. At this time, the arm of the first external force F1 is L1, and the moment that can be born by the elastic element 136 is F1×L1. Further, when pushing the push button 132 to move the fixing mechanism 130 from the locking position to the release position, the user must provide a second external force F2 to make the elastic element 136 generate elastic deformation in the direction indicated by the arrow 140. At this point, the arm of the second external force F2 is L2, and the moment that can be born by the elastic element 136 is F2×L2.

It should be noted that the moments for the elastic element 136 to generate elastic deformation in the direction indicated by the arrow 140 are substantially the same, but the lengths of the arms L1 and L2 are different, so the first external force F1 and the second external force F2 are different. Therefore, the minimal external force provided by the user to push the push button 132 to move from the release position to the locking position and the minimal external force provided by the user to push the push button 132 to move from the locking position to the release position are different.

FIG. 3 is a schematic structural view of the body of another fixing mechanism. Referring to FIG. 3, the structure of the body 134b of the fixing mechanism is substantially the same as the structure of the body shown in FIGS. 2A and 2B, except that the body 134b has two elastic elements 136. Similarly, since the lengths of the arms L1 and L2 are different, the first external force F1 and the second external force F2 are different. In addition, since the elastic elements 136 are protruding from one side of the body 134b, the fixing mechanism needs a larger space for assembling.

### SUMMARY OF THE INVENTION

The present invention provides a fixing mechanism which allows the user to push the fixing mechanism to move from a release position to a locking position or from the locking position to the release position by exerting substantially the same external force.

The present invention provides a fixing mechanism suitable to be assembled with an electronic device having at least one first limiting portion, so as to fix a removable device to the electronic device. The fixing mechanism includes a body, a positioning unit, and at least one elastic element. The body is disposed in the electronic device, and the positioning unit is disposed at one side of the body. The elastic element is connected to the body and includes a first arm, a second arm, and a second limiting portion. The second arm is symmetric to the first arm, and one end of the first arm and one end of the second arm are respectively connected to the body. The length of the first arm is substantially equal to the length of the second arm. The second limiting portion is connected between the first arm and the second arm. The body is suitable to move relative to the electronic device along a first direction, such that the first limiting portion moves along the elastic element, and the positioning unit is fixed to the removable device, and the second limiting portion is suitable for limiting the first limiting portion moving along the elastic element.

In an embodiment of the present invention, the first limiting portion is a bump, and the second limiting portion is a protrusion protruding from a moving path of the bump.

In an embodiment of the present invention, the positioning unit is a positioning pin, and the removable device has a positioning hole. The positioning pin is suitable to be inserted in the positioning hole, so as to fix the removable device in the electronic device.

In an embodiment of the present invention, the body has a second hole and the elastic element is disposed between two opposite side walls of the second hole along the first direction.

In an embodiment of the present invention, the fixing mechanism includes two symmetric elastic elements, and the first limiting portion is disposed between the elastic elements.

In an embodiment of the present invention, the fixing mechanism includes two symmetric elastic elements, the electronic device has two first limiting portions corresponding to the elastic elements respectively, and the body is disposed between the second limiting portions.

In an embodiment of the present invention, the fixing mechanism further includes a push button connected to the body, so as to drive the body to move relative to the first limiting portion.

In an embodiment of the present invention, the push button has a hook and the body further has a mounting hole. The push button is engaged with the mounting hole through the hook, so as to be connected to the body.

In an embodiment of the present invention, the body is disposed on an inner surface of a housing of the electronic device, and the push button is disposed on an outer surface of the housing and passes through a first hole of the housing to be connected to the body, so as to drive the body to move relative to the first limiting portion.

In an embodiment of the present invention, one side of the body further has a first sliding slot in an extending direction parallel to the first direction, and the housing further has a first rib corresponding to the first sliding slot. The first rib protrudes from the inner surface of the housing, and the body is limited to move relative to the electronic device along the first direction by the first sliding slot in conjunction with the first rib.

In an embodiment of the present invention, the body further has two second ribs which are disposed in the first sliding slot in an extending direction parallel to the first direction. The body is connected to the first rib through the second ribs.

In an embodiment of the present invention, the body further has a foolproof bump disposed at another side of the body opposite to the first sliding slot.

In an embodiment of the present invention, the outer surface of the housing further has a second sliding slot in an extending direction parallel to the first direction, and the push button is suitable for sliding in the second sliding slot along the first direction.

The present invention further provides a fixing mechanism suitable to be assembled with an electronic device having at least one first limiting portion. The fixing mechanism includes a body and at least one elastic element. The body is disposed in the electronic device, and the elastic element is connected to the body and includes a first arm, a second arm, and a second limiting portion. The second arm is symmetric to the first arm, and one end of the first arm and one end of the second arm are respectively connected to the body. The length of the first arm is substantially equal to the length of the second arm. The second limiting portion is connected between the first arm and the second arm. The body is suitable to move relative to the electronic device along a first direction, such that the first limiting portion moves along the elastic element, and the second limiting portion is suitable for limiting the first limiting portion moving along the elastic element.

In an embodiment of the present invention, the first limiting portion is a bump and the second limiting portion is a protrusion protruding from a moving path of the bump.

In an embodiment of the present invention, the body has a second hole and the elastic element is disposed between two opposite side walls of the second hole along the first direction.

In an embodiment of the present invention, the fixing mechanism includes two symmetric elastic elements, and the first limiting portion is disposed between the elastic elements.

In an embodiment of the present invention, the fixing mechanism includes two symmetric elastic elements, and the electronic device has two first limiting portions corresponding to the elastic elements respectively. The body is disposed between the second limiting portions.

In an embodiment of the present invention, the fixing mechanism further includes a push button. The push button is connected to the body, so as to drive the body to move relative to the first limiting portion.

In an embodiment of the present invention, the push button has a hook and the body further has a mounting hole. The push button is engaged with the mounting hole through the hook, so as to be connected to the body.

In an embodiment of the present invention, the body is disposed on an inner surface of a housing of the electronic device and the push button is disposed on an outer surface of the housing and passes through a first hole of the housing to be connected to the body, so as to drive the body to move relative to the first limiting portion.

In an embodiment of the present invention, one side of the body further has a first sliding slot in an extending direction parallel to the first direction, and the housing further has a first rib corresponding to the first sliding slot. The first rib protrudes from the inner surface of the housing, and the body is limited to move relative to the electronic device along the first direction by the first sliding slot in conjunction with the first rib.

In an embodiment of the present invention, the body further has two second ribs disposed in the first sliding slot in an extending direction parallel to the first direction. The body is connected to the first rib through the second ribs.

In an embodiment of the present invention, the body further has a foolproof bump disposed at another side of the body opposite to the first sliding slot.

In an embodiment of the present invention, the outer surface of the housing further has a second sliding slot in an extending direction parallel to the first direction, and the push button is suitable for sliding in the second sliding slot along the first direction.

In the fixing mechanism provided by the present invention, the first arm is symmetric to the second arm, and the length of the first arm is substantially equal to the length of the second arm. Therefore, the first limiting portion pushes the second limiting portion along the first direction or the direction opposite to the first direction, thereby generating substantially the same minimal external forces required by the elastic element to generate the elastic deformation.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic structural view of a conventional notebook PC.

FIG. 2A is a schematic structural view of a fixing mechanism in a release position in FIG. 1.

FIG. 2B is a sectional view of FIG. 2A taken along a section line I-I′.

FIG. 2C is a schematic structural view of the fixing mechanism in a locking position in FIG. 1.

FIG. 2D is a sectional view of FIG. 2C taken along a section line II-II′.

FIG. 3 is a schematic structural view of a body of another conventional fixing mechanism.

FIG. 4 is a schematic structural view of an electronic device according to a first embodiment of the present invention.

FIGS. 5A and 5B are schematic structural views of a fixing mechanism in the release position and the locking position respectively in FIG. 4.

FIG. 6 is a sectional view of FIG. 5A taken along a section line III-III′.

FIG. 7 is a schematic structural view of a fixing mechanism in a locking position according to a second embodiment of the present invention.

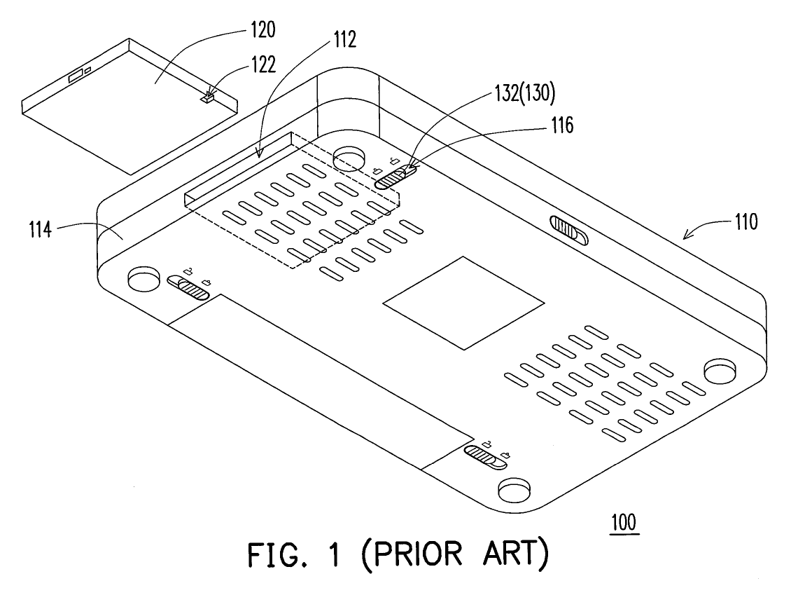

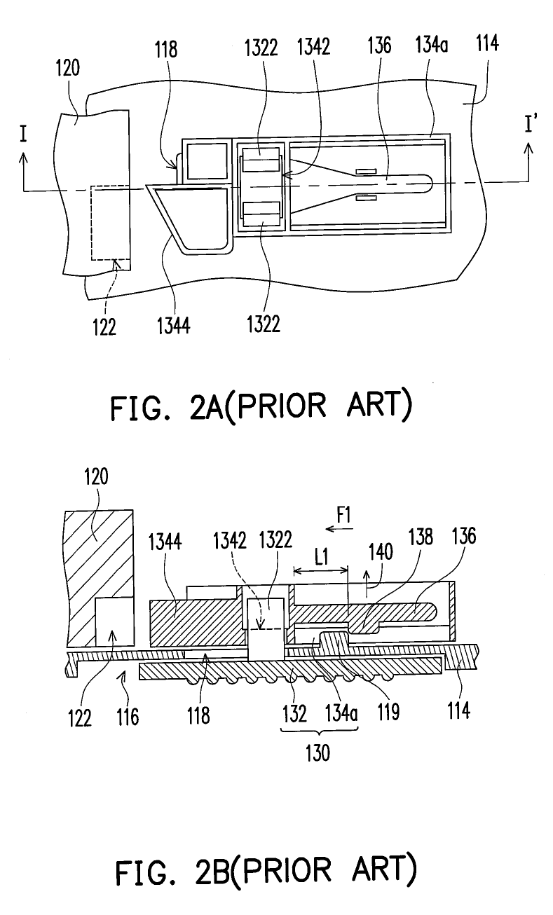

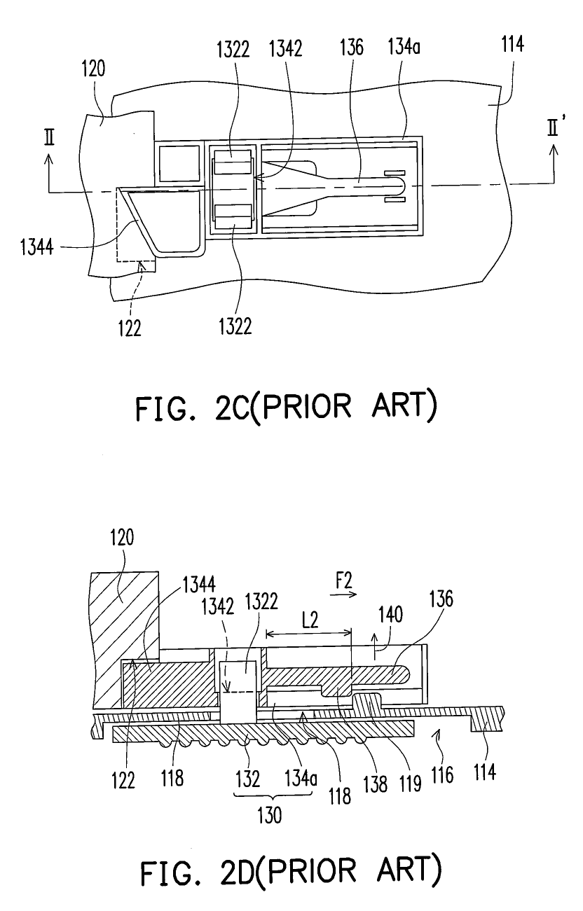

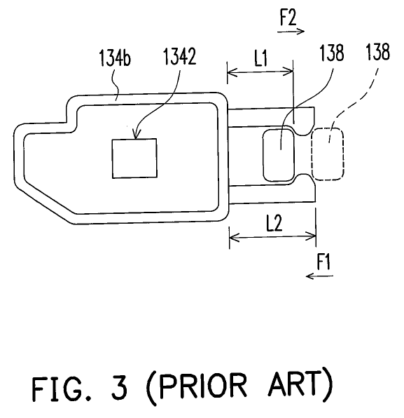

### DESCRIPTION OF EMBODIMENTS

### The First Embodiment

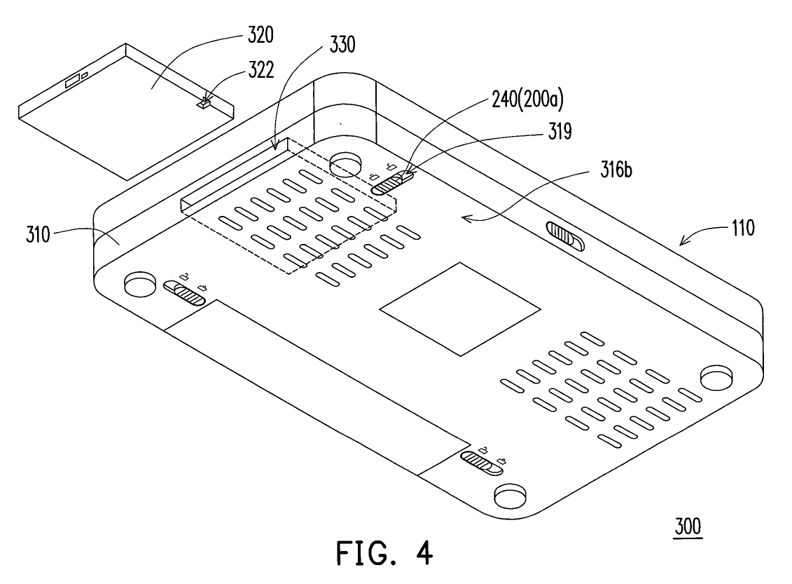

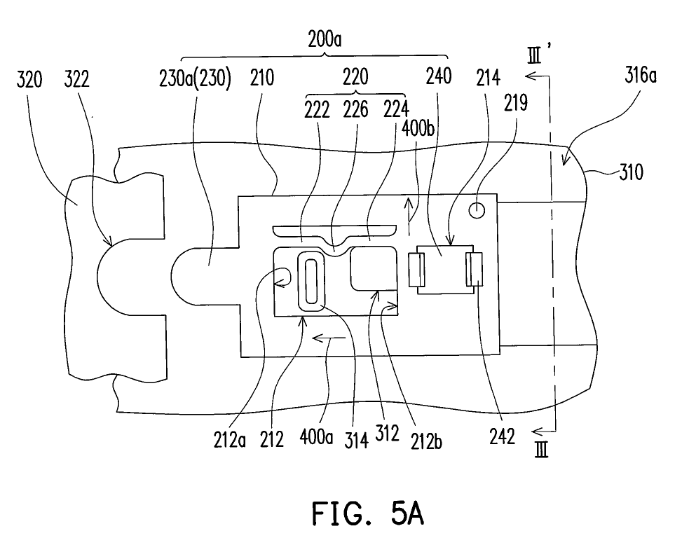

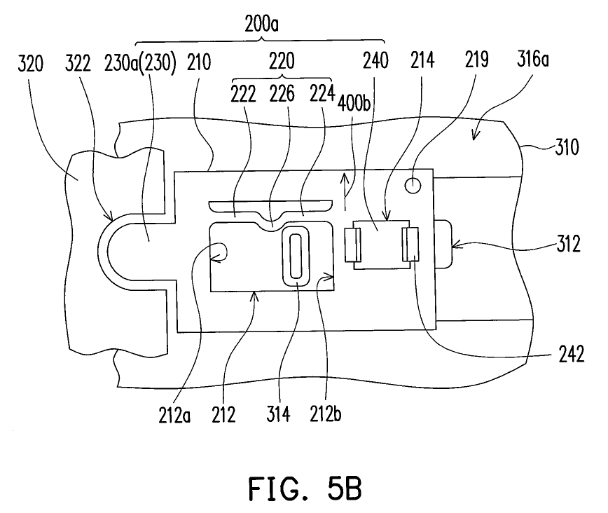

FIG. 4 is a schematic structural view of an electronic device according to a first embodiment of the present invention, and FIGS. 5A and 5B are schematic structural views of a fixing mechanism in a release position and a locking position respectively in FIG. 4. Referring to FIGS. 4-5B, the fixing mechanism 200a is suitable to be assembled with a housing 310 of an electronic device 300, so as to fix a removable device 320 in a slot 330 of the housing 310. In this embodiment, the electronic device 300 is, for example, a notebook PC, and the removable device 320 is, for example, a detachable disc driver. However, in other embodiments, the removable device 320 may also be a battery, a floppy drive, or other detachable devices of a notebook PC.

In this embodiment, the housing 310 further has a first hole 312 and a first limiting portion 314, and the removable device 320 has a positioning hole 322. The fixing mechanism 200a includes a body 210, at least one elastic element 220, a positioning unit 230, and a push button 240. In the following embodiment, for example, the positioning unit 230 is a positioning pin 230a. However, in other embodiments, the removable device 320 can also have a positioning pin, and at this time, the positioning unit of the fixing mechanism 200a may be a positioning hole.

The body 210 is disposed on an inner surface 316a of the housing 310 and has a second hole 212. The elastic element 220 is disposed between the two side walls 212a and 212b of the second hole 212 along a first direction 400a and includes a first arm 222, a second arm 224, and a second limiting portion 226. The first arm 222 is symmetric to the second arm 224, and the length of the first arm 222 is substantially equal to the length of the second arm 224. One end of the first arm 222 is connected to the side wall 212a, and one end of the second arm 224 is connected to the side wall 212b.

The second limiting portion 226 is connected between the first arm 222 and the second arm 224, and is located in a moving path of the first limiting portion 314, such that a release position (in FIG. 5A) and a locking position (in FIG. 5B) of the fixing mechanism 200a may be defined by the relative positions of the first limiting portion 314 and the second limiting portion 226. When the second limiting portion 226 is adjacent to the first arm 222, the fixing mechanism 200a is, for example, located in the release position, and when the second limiting portion 226 is adjacent to the second arm 224, the fixing mechanism 200a is, for example, located in the locking position. The positioning pin 230a is disposed at one side of the body 210, and the push button 240 is disposed in the first hole 312 of the housing 310 and exposed on an outer surface 316b of the housing 310. The push button 240 is fixed in the body 210 and is suitable for driving the body 210 to move relative to the first limiting portion 314 of the electronic device 300. The first limiting portion 314 is, for example, a bump.

In this embodiment, the push button 240 includes two hooks 242, the body 210 has a mounting hole 214, the hook 242 of the push button 240, for example, passes through the first hole 312 to be engaged with the mounting hole 214 of the body 210. Therefore, when the user pushes the push button 240, the hook 242 slides in the first hole 312 and drives the body 210 to move relative to the first limiting portion 314 by the engagement of the hook 242 and the mounting hole 214. However, in other embodiments of the present invention, the push button 240 may be connected to the body 210 by other means.

When the push button 240 drives the body 210 to move relative to the first limiting portion 314 of the electronic device 300, the first limiting portion 314 slides along the elastic element 220 and the positioning pin 230a will be inserted into the positioning hole 322, so as to fix the removable device 320 in the slot 330 of the housing 310. The second limiting portion 226 will limit the first limiting portion 314 moving along the elastic element 220, so as to prevent the body 210 from moving relative to the electronic device 300.

More specifically, when the user pushes the push button 240 to drive the body 210 to move relative to the first limiting portion 314 along the first direction 400a, the fixing mechanism 200 will move from the release position to the locking position to drive the positioning pin 230a to move along the first direction 400a, so as to get close to the positioning hole 322. At this time, the first limiting portion 314 will push the second limiting portion 226 in its moving path, so as to make the elastic element 220 generate lateral elastic deformation along a second direction 400b. When the fixing mechanism 200a reaches the locking position, the elastic element 220 returns to the initial state, such that the second limiting portion 226 prevents the first limiting portion 314 from moving along the elastic element 220, thereby fixing the fixing mechanism 200a in the locking position. At this time, the removable device 320 may be fixed in the slot 330 of the housing 310 through the engagement of the positioning pin 230a and the positioning hole 322.

When the user pushes the push button 240 to drive the body 210 to move relative to the first limiting portion 314 along a direction opposite to the first direction 400a, the fixing mechanism 200a moves from the locking position to the release position, and drives the positioning pin 230a to move in a direction opposite to the first direction 400a to be moved out through the positioning hole 322. At this time, the first limiting portion 314 may also push the second limiting portion 226 in its moving path, so as to make the elastic element 220 generate a lateral elastic deformation along the second direction 400b. When the fixing mechanism 200a reaches the release position, the elastic element 220 returns to the initial state, such that the second limiting portion 226 prevents the first limiting portion 314 from moving along the elastic element 220, thereby fixing the fixing mechanism 200a in the release position. At this time, the removable device 320 may be taken out of the slot 330 of the housing 310.

In this embodiment, since the first arm 222 is symmetric to the second arm 224, and the length of the first arm 222 is substantially equal to the length of the second arm 224. Therefore, the minimal external force required by the first limiting portion 20 314 to push the left side of the second limiting portion 226 (the fixing mechanism 200a moves from the release position to the locking position) to make the elastic element 220 generate elastic deformation along the second direction 400b and the minimal external force required by the first limiting portion 314 to push the right side of the second limiting portion 226 (the fixing mechanism 200a moves from the locking position to the release position) are substantially the same. Therefore, the minimal external force provided by the user to push the push button 240 to insert the positioning pin 230a into the positioning hole 322 and the minimal external force to push the push button 240 to move the positioning pin 230a out of the positioning hole 322 are substantially the same.

However, the aforementioned embodiment is not used to limit the present invention. For example, the fixing mechanism 200a may not include the push button 240, while the body 210 may be disposed at any other positions, for example, the inner surface 316a. At this time, the user can directly push the body 210 to move, and the housing 310 may not have a first hole 312. Furthermore, the body 210 may not have a second hole 212, the elastic element 220 may be connected to one side of the body 210, and the first limiting portion 314 is disposed corresponding to the elastic element 220. Or, the fixing mechanism 200a may have two elastic elements 220 connected to the opposite sides of the body 210, the housing 310 may have two first limiting portions 314 respectively disposed corresponding to the elastic elements 220.

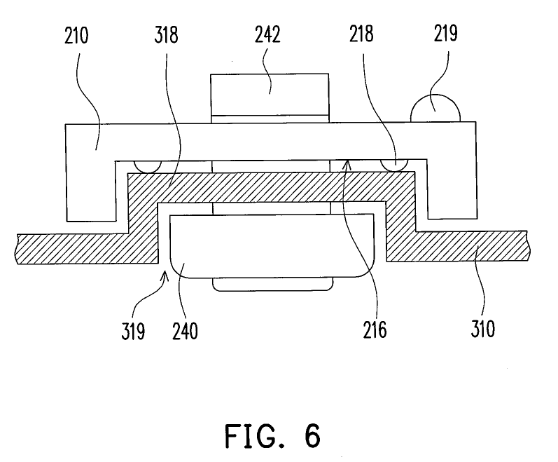

FIG. 6 is a sectional view of FIG. 5A taken along the section line III-III′. Referring to FIGS. 5A and 6, the body 210 may further have a first sliding slot 216 and two second ribs 218, and the housing 310 may further have a first rib 318 and a second sliding slot 319. The first rib 318 and the second sliding slot 319 of the housing 310 are, for example, integrated into one piece, such that the first rib 318 and the second sliding slot 319 are simultaneously formed on the inner surface 316a and the outer surface 316b of the housing 310 in an extending direction parallel to the first direction 400a. Furthermore, the first rib 318 corresponds to the first sliding slot 216, such that when the body 210 is assembled to the housing 310, the body 210 is limited to move relative to the first limiting portion 314 along the first direction 400a by the first sliding slot 216 in conjunction with the first rib 318.

In addition, the second rib 218 protrudes from the first sliding slot 216 toward the first rib 318 and extends in a direction parallel to the first direction 400a. In this embodiment, the body 210 may be connected to the first rib 318 through the second rib 218, so as to reduce the contact area between the body 210 and the housing 310, thereby reducing the friction force generated when the body 210 moves relative to the first limiting portion 314 along the first direction 400a. Additionally, the body 210 can further have a foolproof bump 219 disposed at another side of the body 210 opposite to the first sliding slot 216. Since the foolproof bump 219 and the first sliding slot 216 will make the opposite sides of the body 210 forming an asymmetric structure, the body 210 cannot be assembled to the housing 310 when the user makes the first sliding slot 216 facing the first rib 318 with its back side.

### The Second Embodiment

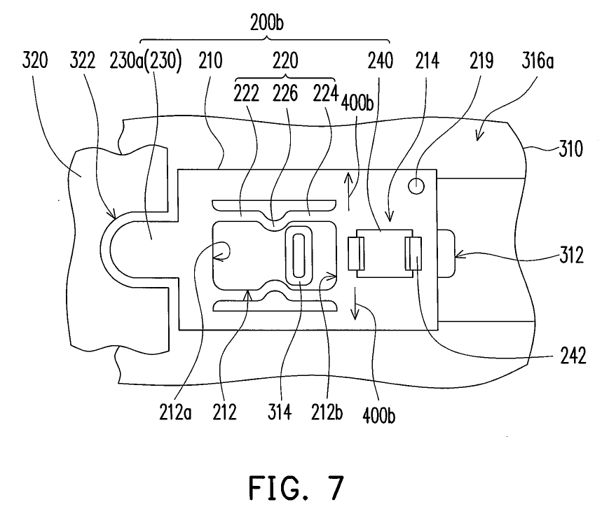

FIG. 7 is a schematic structural view of a fixing mechanism in a locking position according to a second embodiment of the present invention. Referring to FIG. 7, the structure of the fixing mechanism 200b is substantially the same as that of the fixing mechanism 200a as shown in FIG. 5B, except that the fixing mechanism 200b includes two symmetric elastic elements 220, and the first limiting portion 314 is disposed between the elastic elements 220.

In this embodiment, since the first limiting portion 314 is disposed between the elastic elements 220, when the user pushes the push the button 240 to fix the removable device 320 in the slot 330 of the housing 310, the first limiting portion 314 may simultaneously push the second limiting portions 226 of the elastic elements 220. Moreover, when the fixing mechanism 200b reaches the locking position, the elastic elements 220 restores the initial state, such that the second limiting portion 226 prevents the first limiting portion 314 from moving along the elastic element 220, thereby fixing the fixing mechanism 200b at the locking position. The structure and actuation method of the elastic elements 220 are the same as those in the first embodiment, and the details will not be repeated herein.

It should be noted that the present invention is not limited to the aforementioned embodiments. For example, the fixing mechanisms 200a and 200b may not have the positioning unit 230 (the positioning pin 230a). At this time, the fixing mechanisms 200a and 200b may further be applied to a switch between the keyboard and a liquid crystal screen of a notebook PC or other two-stage switches.

In view of the above, in the fixing mechanism of the present invention, since the first arm is symmetric to the second arm, when the fixing mechanism moves from the release position to the locking position or from the locking position to the release position, the external forces exerted by the user on the fixing mechanism are substantially the same. Furthermore, compared with the elastic element of the conventional fixing mechanism being disposed at one side of the body, the elastic element of the present invention can be disposed in the second hole of the body. Therefore, the present invention can further reduce the space for assembling the fixing mechanism. Meanwhile, the fixing mechanism of the present invention may save the material cost by reducing the whole volume thereof.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fixing mechanism, suitable to be assembled with an electronic device having at least one first limiting portion, so as to fix a removable device in the electronic device, the fixing mechanism comprising:
a body, disposed in the electronic device;
a positioning unit, disposed at one side of the body; and
at least one elastic element, connected to the body, and comprising:
a first arm;
a second arm symmetric to the first arm, wherein one end of the first arm and one end of the second arm are connected to the body respectively, and the length of the first arm is substantially equal to the length of the second arm; and
a second limiting portion, connected between the first arm and the second arm, wherein the body is suitable to move relative to the electronic device along a first direction, such that the first limiting portion moves along the elastic element and the positioning unit is fixed to the removable device, and the second limiting portion is suitable for limiting the first limiting portion to move along the elastic element.

2. The fixing mechanism as claimed in claim 1, wherein the first limiting portion is a bump and the second limiting portion is a protrusion protruding from a moving path of the bump.

3. The fixing mechanism as claimed in claim 1, wherein the positioning unit is a positioning pin, the removable device has a positioning hole, and the positioning pin is suitable to be inserted into the positioning hole, so as to fix the removable device in the electronic device.

4. The fixing mechanism as claimed in claim 1, wherein the body has a second hole, and the elastic element is disposed between two opposite side walls of the second hole along the first direction.

5. The fixing mechanism as claimed in claim 4, comprising two symmetric elastic elements, wherein the first limiting portion is disposed between the elastic elements.

6. The fixing mechanism as claimed in claim 1, comprising two symmetric elastic elements, wherein the electronic device has two first limiting portions respectively corresponding to the elastic elements, and the body is disposed between the second limiting portions.

7. The fixing mechanism as claimed in claim 1, further comprising a push button, wherein the push button is connected to the body, so as to drive the body to move relative to the first limiting portion.

8. The fixing mechanism as claimed in claim 7, wherein the push button has a hook, the body further has a mounting hole, and the push button is engaged with the mounting hole through the hook, so as to be connected to the body.

9. The fixing mechanism as claimed in claim 7, wherein the body is disposed on an inner surface of a housing of the electronic device, and the push button is disposed on an outer surface of the housing and passes through a first hole of the housing to be connected to the body, so as to drive the body to move relative to the first limiting portion.

10. The fixing mechanism as claimed in claim 9, wherein one side of the body further has a first sliding slot in an extending direction parallel to the first direction, the housing further has a first rib corresponding to the first sliding slot, the first rib protrudes from the inner surface of the housing, and the body is limited to move relative to the electronic device along the first direction by the first sliding slot in conjunction with the first rib.

11. The fixing mechanism as claimed in claim 10, wherein the body further has two second ribs which are disposed in the first sliding slot in an extending direction parallel to the first direction, and the body is connected to the first rib through the second rib.

12. The fixing mechanism as claimed in claim 10, wherein the body further has a foolproof bump disposed on another side of the body opposite to the first sliding slot.

13. The fixing mechanism as claimed in claim 9, wherein the outer surface of the housing further has a second sliding slot in an extending direction parallel to the first direction, and the push button is suitable for sliding in the second sliding slot along the first direction.

14. A fixing mechanism, suitable to be assembled with an electronic device having a first limiting portion, the fixing mechanism comprising:
a body, disposed in the electronic device; and
at least one elastic element, connected to the body, and comprising:
a first arm;
a second arm symmetric to the first arm, wherein one end of the first arm and one end of the second arm are respectively connected to the body, and the length of the first arm is substantially equal to the length of the second arm; and
a second limiting portion, connected between the first arm and the second arm, wherein the body is suitable to move relative to the electronic device along a the first direction, such that the first limiting portion moves along the elastic element and the second limiting portion is suitable for limiting the movement of the first limiting portion.

15. The fixing mechanism as claimed in claim 14, wherein the first limiting portion is a bump and the second limiting portion is a protrusion protruding from a moving path of the bump.

16. The fixing mechanism as claimed in claim 14, wherein the body has a second hole and the elastic element is disposed between two opposite side walls of the second hole along the first direction.

17. The fixing mechanism as claimed in claim 16, comprising two symmetric elastic elements, wherein the first limiting portion is disposed between the elastic elements.

18. The fixing mechanism as claimed in claim 14, comprising two symmetric elastic elements, wherein the electronic device has two first limiting portions respectively corresponding to the elastic elements, and the body is disposed between the second limiting portions.

19. The fixing mechanism as claimed in claim 14, further comprising a push button, wherein the push button is connected to the body, so as to drive the body to move relative to the first limiting portion.

20. The fixing mechanism as claimed in claim 19, wherein the push button further comprises a hook, the body further has a mounting hole, and the push button is engaged with the mounting hole through the hook, so as to be connected to the body.

21. The fixing mechanism as claimed in claim 19, wherein the body is disposed on an inner surface of a housing of the electronic device, and the push button is disposed on an outer surface of the housing and passes through a first hole of the housing to be connected to the body, so as to drive the body to move relative to the first limiting portion.

22. The fixing mechanism as claimed in claim 21, wherein one side of the body further has a first sliding slot in an extending direction parallel to the first direction, and the housing further has a first rib corresponding to the first sliding slot, the first rib protrudes from the inner surface of the housing, and the body is limited to move relative to the first limiting portion along the first direction by the first sliding slot in conjunction with the first rib.

23. The fixing mechanism as claimed in claim 22, wherein the body further has two second ribs which are disposed in the first sliding slot in an extending direction parallel to the first direction, and the body is connected to the first rib through the second rib.

24. The fixing mechanism as claimed in claim 22, wherein the body further has a foolproof bump disposed at another side of the body opposite to the first sliding slot.

25. The fixing mechanism as claimed in claim 21, wherein the outer surface of the housing further has a second sliding slot in an extending direction parallel to the first direction, and the push button is suitable for sliding in the second sliding slot along the first direction.
